(19) United States
(12) Patent Application Publication
(10) Pub. No.: US 2011/0183156 A1
(43) Pub. Date: Jul. 28, 2011

(54) SACRIFICIAL ANODIC COATINGS FOR MAGNESIUM ALLOYS

(75) Inventor: Guangling Song, Troy, MI (US)

(73) Assignee: GM GLOBAL TECHNOLOGY OPERATIONS, INC., DETROIT, MI (US)

(21) Appl. No.: 12/694,335

(22) Filed: Jan. 27, 2010

(51) Int. Cl. B32B 15/01; C23C 14/34; C25D 3/00

(52) U.S. Cl. 428/649; 204/192.15; 205/261

(57) ABSTRACT

Elemental magnesium coatings and methods of applying them to surfaces of magnesium-based alloy articles of manufacture are described. Such coatings may be chosen to be anodic to magnesium and may thus, when applied to magnesium articles, be sacrificial and afford corrosion protection to the articles. The utility of such coatings may be enhanced by supplementing them with a barrier coating such as a passive magnesium-containing alloy, a conversion or anodic coating or paint overlying the sacrificial coating. Methods of applying sacrificial coatings to a magnesium-based alloy article are described and include physical vapor deposition on the article, electrodeposition on the article and dipping the article in molten alloy.

TECHNICAL FIELD

This invention pertains to methods and coatings for protection of articles fabricated of magnesium and magnesium alloys from corrosive attack.

### BACKGROUND OF THE INVENTION

Magnesium and magnesium alloy articles continue to enjoy application in mass-sensitive applications such as automobiles since their low density and good strength-to-weight ratio enable appreciable mass reduction over more conventional materials such as low carbon steels.

However magnesium is very chemically active and, if unprotected, will readily corrode in the presence of water and aqueous electrolytes. Thus, exposure to water or water and road salt, a frequent occurrence for automobiles operated in snow-prone regions, could promote unacceptable corrosion in magnesium components. For this reason, much attention has been directed to methods of protecting magnesium and its alloys from corrosion-promoting environments.

Two general approaches to protecting metals from corrosion are commonly employed; sacrificial protection and barrier layer protection. Sacrificial protection, exemplified by the application of zinc to ferrous alloys, applies a coating of a more corrodible composition or material to the article to be protected so that under exposure to corrosive conditions the coating will corrode in preference to the article. That is, the coating is anodic with respect to the article and is thus sacrificed to protect the article. Barrier layer protection, by contrast seeks to prevent access of the corrosive medium to the article by applying an impermeable, non-corrosive coating to the article to bar access of the corrosive medium to the article.

Of these approaches, sacrificial coatings are preferred since they continue to convey corrosion protection, for at least as long as it takes to consume the sacrificial coating, even if scratched, ruptured or otherwise damaged. Barrier coatings by contrast, if damaged and breached, offer no further protection and may even promote more aggressive corrosion since the anodic region will generally be significantly less extensive than the cathodic region.

A requirement for a sacrificial coating is that the coating be more electrochemically active than the article to be protected and that it is essentially nonreactive in non-corrosive environments. Very few elements are more electrochemically-active than magnesium and those which are, such as lithium or calcium, tend to be so active that they react extensively in most environments. Thus, their beneficial corrosion-protecting capability may be expended prematurely leaving them unable to protect the article when it is exposed to a corrosive environment.

Hence, most methods of protecting magnesium from corrosion have relied on the application of barrier coatings despite their attendant disadvantages. There thus remains a need for an enhanced corrosion protection system for magnesium and magnesium articles which conveys sacrificial protection to the article.

### SUMMARY OF THE INVENTION

This invention seeks to protect a magnesium or magnesium-based alloy article by employing a sacrificial coating, which is one which when applied to a surface of the magnesium article and exposed to a corrosive environment will preferentially corrode and thereby suppress corrosion of the magnesium article. A thin coating of substantially elemental magnesium may be used for this purpose. A coating thickness of the order of 500 nanometers to a millimeter or more is formed. In some embodiments of the invention, the elemental magnesium sacrificial coating may be deposited by physical vapor deposition. As is demonstrated below in this specification, elemental magnesium coatings deposited in this method are anodic even to wrought or cast elemental magnesium. In other embodiments of the invention, the sacrificial coating of elemental magnesium may be formed, for example, by electrodeposition, melt coating, or other coating methods.

For further protection of surfaces of a magnesium article, the sacrificial coating may be employed in combination with a passive or inert barrier coating, by utilizing a sacrificial magnesium coating in direct contact with the article and overlaying it with a protective, barrier coating.

It is anticipated that articles formed of commonly used, cast or wrought magnesium alloys such as, AZ31 (nominal composition 3 weight percent aluminum, 1 weight percent zinc, balance magnesium), AZ91 (nominal composition 9 weight percent aluminum, 1 weight percent zinc, balance magnesium), AS21 (nominal composition 2 weight percent aluminum, 1 weight percent silicon, balance magnesium), AM60 (nominal composition 6 weight percent aluminum, 0.13 to 0.60 weight percent manganese, balance magnesium), AE44 (nominal composition 4 weight percent aluminum, 4 weight percent mischmetal (rare earths), balance magnesium) and ZE41 (nominal composition 4 weight percent zinc, 1 weight percent zirconium, 1 weight percent cerium, balance magnesium) among others, could be protected against corrosion by practices of this invention. Many commercially available magnesium-based alloys contain about ninety percent by weight or more magnesium and practices of this invention are applicable to such alloys. And it is believed that the elemental magnesium sacrificial coatings of this invention will protect magnesium alloys containing more than fifty percent by weight magnesium.

By overlaying the sacrificial coating on an article with a barrier coating, the sacrificial coating is protected against some impacts and against premature reaction due to general corrosion resulting from exposure to a corrosive or reactive environment until the barrier layer is breached. Thus, the sacrificial coating will be maintained in a reactive state by the action of the barrier coating in excluding the environment and will become active only upon exposure to the environment resulting from rupture of the barrier layer.

Such a complementary combination marries the benefits of each corrosion-resisting strategy. Thus, the effectiveness of barrier coatings in excluding a reactive or corrosive environment may be employed to protect a more electrochemically-active coating from reaction, thereby eliminating at least one concern over sacrificial coatings. Similarly, the ability of the sacrificial coating to continue to protect the article, despite breach of the barrier layer, overcomes a major concern with barrier coatings.

The invention comprehends the many barrier coatings which have been developed for magnesium and magnesium alloys which include: chemically or electrochemically-formed conversion layers; vapor or plasma spray coating; and paint or polymeric coatings. When the elemental magnesium layer is to be provided with a conversion coating, allowance may be made in the thickness of the magnesium sacrificial layer as some of the magnesium may be consumed in the formation of its conversion coating. As used herein, paint refers to the plurality of coating layers commonly applied to automotive bodies and which collectively achieve a thickness of about 150 micrometers. The layers may include: a corrosion-inhibiting electrodeposit; a primer-surfacer; a basecoat and a clearcoat layer.

It will be particularly beneficial if the barrier coating is harder than magnesium, for example a titanium-containing magnesium alloy, so that the barrier coating may also convey damage- or abrasion-resistance to the article.

It is noted that any coating which is sacrificial to magnesium will likewise be sacrificial to other common structural metals and alloys, for example those based on iron, aluminum, titanium or zinc.

Other embodiments and advantages of this invention will be apparent from a detailed description of illustrative embodiments which follows in this specification. Reference will be made to the drawings which are described in the following section of this specification.

### BRIEF DESCRIPTION OF THE DRAWINGS

FIG. 1 is a fragmentary illustration in cross-section showing a magnesium or magnesium alloy article, overlaid with a sacrificial corrosion protection layer of elemental magnesium which is itself overlaid with a barrier layer. In this illustration, a small portion of both coating layers has been damaged (like a scratch) by some impact on the article exposing a portion of the magnesium article to a corrosive liquid and establishing a current flow from the sacrificial elemental magnesium layer to the magnesium article.

FIG. 2 shows polarization curves, each measured relative to a silver/silver chloride half-cell, showing the corrosion potentials for: a magnesium film deposited by a Physical Vapor Deposition (PVD) process; a bulk sample of cast commercial purity elemental magnesium; and two Mg-Ti co-deposited PVD films, one with an atomic ratio of Mg to Ti of 1:1 and the other with an atomic ratio of Mg to Ti of 1:3.

### DESCRIPTION OF PREFERRED EMBODIMENTS

The environment typical of that encountered by automobiles, particularly those where chemicals such as salt are used to clear snow and ice from roads, promotes corrosion and mandates that automotive materials exposed to that environment be protected. While this is challenging for all automotive materials it presents particular challenges for magnesium or magnesium alloys (for simplicity hereafter, magnesium) due to their highly reactive nature and inability to form a protective oxide layer.

Thus, much effort has been directed to controlling the corrosion of magnesium, primarily through the development of barrier layers, such as conversion coatings, anodized coatings and multi-layer paint coatings, sometimes applied in combination, intended to isolate the magnesium from the corrosive environment.

Some conversion coatings may be based on stannates and produced, for example, by immersing an article comprising magnesium in a solution containing 10-12 g/L sodium hydroxide, 40-50 g/L potassium stannate, 10-25 g/L sodium acetate and 40-50 g/L tetra sodium pyrophosphate at 82° C., pH 11.6, for 20 minutes while under continuous agitation.

Other conversion coatings may be based on cerium oxide and produced, for example, by immersing an article comprising magnesium in a solution of 5 g/L cerium sulphate and 40 ml/L hydrogen peroxide at room temperature, pH 2.0 for 3-4 minutes.

And yet other conversion coatings based on chromate may be obtained, for example by immersing an article comprising magnesium by immersing in a solution containing 10 g/L chromic acid and 7.5 g/L calcium sulphate at room temperature, pH 1.2 for 30-60 seconds.

It is well-recognized that while intact barrier layers or barrier coatings are effective, any local rupture of the coating which exposes the underlying magnesium tends to promote more intense local corrosion than would occur if the entire surface were exposed to the corrosive medium. It is also recognized that a more preferable approach to corrosion protection or control is to provide a layer of a more chemically-active species which will preferentially corrode and thereby protect the magnesium.

Magnesium however is one of the most electrochemically-active elements with only a limited number of elements including Ca, Na, K and Li being more active. Moreover, these more-active elements are themselves subject to rapid reaction and corrosion if unprotected. Thus it may be beneficial to protect any sacrificial coating from general corrosion. Hence in a first embodiment this invention comprehends the application of a sacrificial coating in direct contact with magnesium and, in a second embodiment, the application of a sacrificial coating in direct contact with magnesium followed by the application of a barrier layer to protect the sacrificial coating and maintain its activity until the barrier layer is damaged or breached.

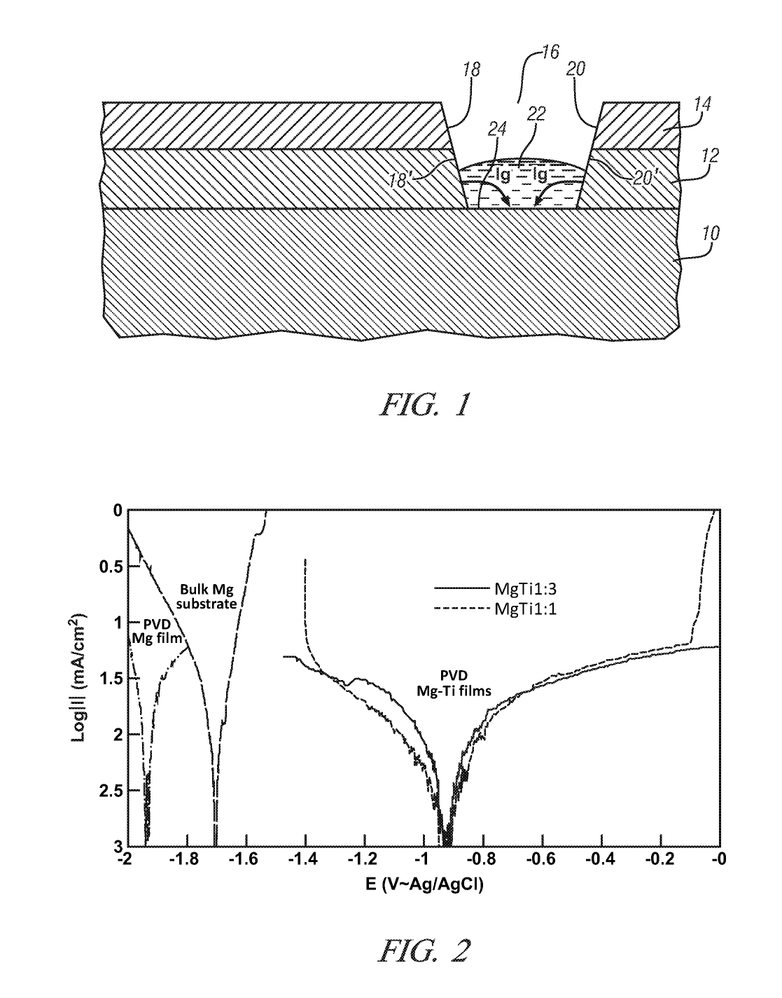

Such a second embodiment is shown in FIG. 1 in which a magnesium surface 10 is overlaid with a more electrochemically-active layer of elemental magnesium 12 and by a barrier layer 14. The thickness of the sacrificial magnesium layer 12 is at least 500 nanometers and preferably a millimeter or more up to a few millimeters. The barrier layer is shown as a single layer for convenience and in further discussion herein may be treated as a single entity. More detailed description or representation, such as the plurality of layers comprising automotive paint, conveys no additional insight into the nature of the invention. Small portions of the sacrificial layer 12 and barrier layer 14 are shown as removed, by abrasion or similar process at location 16, where the respective layer damage boundaries 18, 18′ and 20, 20′ are illustrated. A small quantity of corrosive liquid 22 (e.g., water or salt water) is shown in contact with magnesium surface and the bounding edges 18′ and 20′ of the sacrificial layer 12, resulting in the sacrificial corrosion of sacrificial layer 12 and associated galvanic corrosion currents I_{g}.

It will be appreciated that barrier layer 14 takes no part in this electrochemical reaction. Thus, the electrochemical behavior of a magnesium article 10 coated with only a breached sacrificial layer 12 will be identical to that shown in FIG. 1. However, absent the protection afforded sacrificial layer 12 by barrier layer 14, sacrificial layer 12 will be subject to continuing general corrosion, much like magnesium itself.

Surprisingly it has been found that a nominally pure magnesium film, deposited using physical vapor deposition processes is anodic with respect to commercial-purity cast magnesium and thus can adopt the role of a sacrificial coating. This is demonstrated by the data of FIG. 2 which shows potentiodynamic polarization curves for a PVD magnesium film, bulk magnesium and two Mg—Ti co-deposited films of differing Mg:Ti ratios.

Potentiodynamic polarization is an electrochemical technique by which the potential of an electrode in an electrolyte is displaced from its open-circuit potential by application of a current. The electrochemical potential of each substance investigated, here referred to an Ag/AgCl reference electrode, may be estimated from the potential corresponding to a substantially zero current. A corrosive solution of (0.1N NaCl+1.0 N Na₂SO₄+Mg(OH)₂) was employed as the electrolyte in all cases. From the data of FIG. 2 it may be observed that the deposited magnesium film is more electronegative (about −1.95 volts) than the bulk magnesium (about −1.7 volts) and that both Mg—Ti compositions, one of molar Mg:Ti ratio of 1:1 and the other with a molar Mg:Ti ratio of 1:3 are passive based on the general constancy of the polarization current density over the potential range from −0.7 V to −0.1V. Thus the PVD-deposited magnesium film is anodic with respect to bulk magnesium.

The films, both magnesium and magnesium-titanium, were deposited on substrates held at about 25° C. using individual dc magnetron sputtering of the appropriate target, Mg or Ti, under a flowing argon atmosphere of 14 sccm (standard cubic centimeters per minute) while maintaining a dynamic pressure of 2 mTorr. The thickness of the elemental magnesium layer was in the range of about 500 nanometers to about 900 nanometers. The thickness of the magnesium titanium layers were also about a millimeter. The compositions of the co-deposited Mg—Ti films were controlled and adjusted by controlling the power input to each target and chemical homogeneity was assured by rotating the targets to enable uniform deposition in all regions of the target.

The data shown in FIG. 2 makes clear that a PVD-deposited magnesium layer would be sacrificial to commercially-pure magnesium and thus demonstrates the feasibility of sacrificial protection for magnesium as well as its alloys.

If combined sacrificial and barrier protection is desired it could be readily achieved by applying a PVD-deposited layer of magnesium on the magnesium article, then, using the same chamber, applying a layer of PVD-deposited Mg—Ti.

However, while it may be desirable to employ Mg—Ti as the barrier layer, possibly because of its higher hardness and abrasion resistance, the corrosion benefits of the combined sacrificial-barrier layer approach may be obtained with any of a number of barrier coatings of demonstrated effectiveness. These include paint and a variety of chemically-applied and electrochemically-applied conversion coatings, among others as are well known to those skilled in the art.

While such theory is not relied on it is believed that the more negative potential of the Mg thin film may be associated with its crystallographic orientation relative to the surface. In the deposited films the normal to the basal or (0002) crystallographic planes of the hexagonal magnesium crystals are oriented generally perpendicular to the surface on which they are deposited.

It appears that other low temperature deposition processes would yield similarly high energy deposits with electrochemical potential below that of bulk magnesium and would therefore be similarly sacrificial to bulk magnesium. For example magnesium coatings electrodeposited from non-aqueous plating solutions, such as are described by Mayer in “Electrodeposition of magnesium and magnesium/aluminum alloys”, U.S. Pat. No. 4,778,575 may be effective since Mayer's preferred deposition temperature lies between 40° C. and 70° C. (Col. 5, line 10).

The degree of protection afforded by a sacrificial coating is directly proportional to the quantity or thickness of the coating. Thus for extended corrosion protection heavier coating weights are preferred and it may be desirable to employ procedures for applying the sacrificial coating suitable for rapidly depositing thick coating layers.

One approach, analogous to that employed in galvanizing steel is to dip the magnesium article into a molten bath of the sacrificial coating material. Given the electronegativity of magnesium however and the extreme reactivity of the more electronegative elements, a preferred coating is a magnesium alloy, particularly a magnesium alloy comprising up to 5.5 percent by weight of lithium which is known to be electronegative with respect to magnesium and therefore capable of conveying the desired sacrificial properties. Clearly the melting of such alloys should be conducted under suitably protective conditions as are well known to those skilled in the art to minimize reaction between the melt and the atmosphere.

However, unlike galvanizing of steel, where the melting points of the sacrificial coating (zinc) and the steel manufactured article are markedly different, the melting points of magnesium and many of its commercially-significant alloys are similar, generally differing by less than about 150° C. Also a suitable dip temperature should lie above the liquidus of the sacrificial coating but below the solidus of the article to be plated. The liquidus temperature of a single-phase (at room temperature) binary magnesium-5.5 weight percent lithium alloy is only about 35° C. below the melting point of pure magnesium. Hence this approach, if restricted to binary Mg-Li sacrificial alloys is most suited to depositing a sacrificial coating on substantially pure magnesium.

It is known however that the addition of ternary or quaternary alloying elements will often further depress the liquidus temperature. For example the liquidus temperature of a nominal 8 weight percent lithium, 4 weight percent calcium, and balance magnesium alloy composition lies about 80° C. below the melting point of magnesium. Thus, more complex sacrificial layer compositions may be suitable for application to at least some of the more commonly-used magnesium-based alloys, and in particular alloy-lean compositions such as AZ31, AM60 and others, including those Mg alloys which do not comprise aluminum.

Magnesium is highly reactive and readily forms an oxide on exposure to air, the oxide subsequently being transformed to the hydroxide on exposure to moisture or humidity. Thus it may be preferred to clean or otherwise prepare the surface of a magnesium article prior to depositing the sacrificial coating. Generally, cleaning should be conducted at a temperature of about 85° C. using a highly alkaline aqueous solution at a pH of between 10 and 12, for example comprising sodium hydroxide and sodium carbonate each at about 3% by weight and also comprising small quantities of surfactant. Cathodic electrocleaning may also be used. If the magnesium is to be electrodeposited on the article it may also be beneficial to further prepare the surface of the article by an acid treatment, for example with a chromic acid/nitric acid mixture at room temperature. The acid treatment may be followed by a second surface preparation treatment, comprising, for example, a phosphoric acid/ammonium bifluoride treatment.

As has been described previously, the effectiveness of such sacrificial coatings may be supplemented and further enhanced by overlaying the sacrificial coating with a barrier coating.

The utility of this approach is not limited to its application to exclusively magnesium-based articles. It will be appreciated that any coating which is sacrificial to magnesium will, because magnesium is the most electronegative of the structural metals, be similarly sacrificial to other structural metals in common use. For example the coating and corrosion-resisting approaches described herein may be applied to a wide range of structural metals such as, without limitation, steel, aluminum and its alloys, titanium and its alloys and zinc and its alloys.

Thus, the detailed description and specific examples provided, while disclosing exemplary embodiments of the invention, are intended to be illustrative of the invention and are not intended to limit its scope.

1. An article of manufacture comprising at least a portion that is formed of a cast or wrought magnesium-base alloy comprising at least 90% by weight of magnesium, the magnesium-base alloy portion having a surface that in the intended use of the article is susceptible to corrosion in a water-containing environment, the surface of the magnesium-base alloy having an adherent coating consisting essentially of elemental magnesium and which is anodic to the magnesium base alloy portion in a water containing environment.

2. The article of manufacture of claim 1, further comprising the magnesium coating being coated with a passive barrier layer.

3. The article of manufacture of claim 2 wherein the barrier layer is paint.

4. The article of manufacture of claim 2 wherein the barrier layer is a magnesium alloy which is harder than the elemental magnesium.

5. The article of manufacture of claim 2 wherein the barrier layer is a chemical conversion coating or anodized coating formed by reaction of reactants in aqueous solution with the elemental magnesium.

6. A method of providing protection against corrosion in a water containing environment to a surface of a magnesium-base alloy article, the method comprising:
forming a coating of substantially elemental magnesium on the surface, the coating having a thickness for providing sacrificial protection against such corrosion when the coating on the article is broken and the magnesium alloy surface exposed to water.

7. The method of providing protection against corrosion of claim 6 further comprising forming a protective barrier coating over the magnesium coating.

8. The method of claim 7 wherein the magnesium layer is formed by physical vapor deposition and a barrier coating of a solid solution of magnesium and at least one other element is formed by physical vapor deposition.

9. The method of claim 6 wherein the magnesium layer is formed by electro-deposition of magnesium.

10. The method of claim 7 wherein the barrier layer is formed by applying a paint layer on the magnesium.

11. An article of manufacture comprising at least a portion that is formed of a cast or wrought magnesium-base alloy comprising at least 50% by weight of magnesium, the magnesium-base alloy portion having a surface that in the intended use of the article is susceptible to corrosion in a water-containing environment, the surface of the magnesium-base alloy having an adherent coating consisting essentially of elemental magnesium and which is anodic to the magnesium base alloy portion in a water containing environment.

12. The article of manufacture of claim 11, further comprising the magnesium coating being coated with a passive barrier layer.

13. The article of manufacture of claim 12 wherein the barrier layer is paint.

14. The article of manufacture of claim 12 wherein the barrier layer is a magnesium alloy which is harder than the elemental magnesium.

15. The article of manufacture of claim 1 in which the coating of essentially elemental magnesium has a thickness of at least five hundred nanometers.

16. The article of manufacture of claim 1 in which the coating of essentially elemental magnesium has a thickness up to about three millimeters.

17. The article of manufacture of claim 12 in which the coating of essentially elemental magnesium has a thickness of at least five hundred nanometers.

18. The article of manufacture of claim 12 in which the coating of essentially elemental magnesium has a thickness up to about three millimeters.
